(19) United States
(12) Patent Application Publication
(10) Pub. No.: US 2026/0031832 A1
(43) Pub. Date: Jan. 29, 2026

(54) ADAPTIVE LOSSY COMPRESSION FOR BLACK-BOX CLASSIFICATION MODELS WITH LABEL-LESS DATA

(71) Applicant: Dell Products L.P., Round Rock, TX (US)

(72) Inventors: Rômulo Teixeira de Abreu Pinho, Niterói (BR); Vinicius Michel Gottin, Rio de Janeiro (BR); Paulo de Figueiredo Pires, Niterói (BR); Alex Laier Bordignon, Niterói (BR); Franklin Jordan Ventura Quico, Niterói (BR); João Victor Daher Daibes, Niterói (BR)

(21) Appl. No.: 18/784,781

(22) Filed: Jul. 25, 2024

(51) Int. Cl. H03M 7/30

(52) U.S. Cl. CPC H03M 7/3084

(57) ABSTRACT

A method for an adaptive compression scheme that dynamically adjusts to data characteristics, maintaining model classification accuracy while optimizing compression efficiency, the method including receiving, from an edge device, a sample of compressed data and a sample of raw data that has not been compressed, and the sample of compressed data and the sample of raw data are unlabeled, decompressing the compressed data to obtain decompressed data, and classifying, with an ML (machine learning) model, the decompressed data, using the ML model and the raw data to update a compression quality parameter, and transmitting the compression quality parameter to the edge device, and the compression quality parameter is usable by the edge device to control compression of a subsequent sample of compressed data.

### TECHNOLOGICAL FIELD OF THE DISCLOSURE

Embodiments disclosed herein generally relate to data compression. More particularly, at least some embodiments relate to systems, hardware, software, computer-readable media, and methods, for compressing data to be used by a classification model.

### BACKGROUND

The use of data compression techniques may be used to reduce bandwidth consumption during data transmission for classification models, which may comprise ML (machine learning) models for example. Typically, determining the compression rate is performed with the use of empirical techniques, which require a deep understanding of the classification model, and often involve multiple iterations with different data qualities to evaluate the model's accuracy. Moreover, an approach based on empirical techniques has significant limitations as it relies on the availability of data labels and prior knowledge of the classification model. Such data labels may be time consuming to determine and apply.

In more detail, when a classification model is running in the cloud, for example, it is necessary to upload data to perform inferences using this model, which can be time series, photos, audio, video, or other types of vectors. If the number of inferences is large, or the data throughput to and/or through the model is limited by resources or other constraints, it typically becomes necessary to compress these data. This, however, may incur increased error and/or a drop in quality when performing the inference. This is even more challenging in use cases where data distributions change over time, leading to different ideal compression parameterizations.

### BRIEF DESCRIPTION OF THE DRAWINGS

In order to describe the manner in which at least some of the advantages and features of one or more embodiments may be obtained, a more particular description of embodiments will be rendered by reference to specific embodiments thereof which are illustrated in the appended drawings. Understanding that these drawings depict only typical embodiments and are not therefore to be considered to be limiting of the scope of this disclosure, embodiments will be described and explained with additional specificity and detail through the use of the accompanying drawings.

FIG. 1 discloses aspects of an example method, according to one embodiment.

FIG. 2 discloses aspects of an example method for updating a KL curve, according to one embodiment.

FIG. 3 discloses an example of the use of a KL stability radius curve to calculate the probability of a given sample and its perturbation being classified in the same class, according to one embodiment.

FIG. 4 discloses an example compression quality vs accuracy curve, generated according to one embodiment.

FIG. 5 discloses the calculation of a new compression quality value q, based on a curve that correlates accuracy with compression quality, according to one embodiment.

FIG. 6 discloses aspects of an example use case involving digital images.

FIG. 7 discloses aspects of the outcome of an example use case involving digital images.

FIG. 8 discloses a computing entity configured and operable to perform any of the disclosed methods, processes, and operations.

### DETAILED DESCRIPTION OF SOME EXAMPLE EMBODIMENTS

Embodiments disclosed herein generally relate to data compression. More particularly, at least some embodiments relate to systems, hardware, software, computer-readable media, and methods, for compressing data to be used by a classification model.

In general, one or more embodiments may be directed to methods which comprise an adaptive compression scheme that dynamically adjusts to data characteristics, maintaining model accuracy while optimizing compression efficiency, and which does not necessitate the creation or use of data labels. One embodiment of such a method, which may be cooperatively implemented by an edge device or IoT (internet of things) device, such as a sensor, and a model residing at a site remote from the edge devices, such as a cloud site, comprises operations including: generating and/or collecting data samples by/at an edge device; compressing a portion of the data samples; transmitting the compressed samples along with some raw, or uncompressed, data samples, from the edge device to a computing cluster at a cloud site; decompressing, at the cluster, the compressed data samples and using the raw samples, along with a model running at the cluster, to calculate a compression quality parameter for a subsequent set of data samples; transmitting the compression quality parameter to the edge device; and, compressing, by the edge device the subsequent set of data samples according to the quality compression parameter.

Embodiments, such as the examples disclosed herein, may be beneficial in a variety of respects. For example, and as will be apparent from the present disclosure, one or more embodiments may provide one or more advantageous and unexpected effects, in any combination, some examples of which are set forth below. It should be noted that such effects are neither intended, nor should be construed, to limit the scope of the claims in any way. It should further be noted that nothing herein should be construed as constituting an essential or indispensable element of any embodiment. Rather, various aspects of the disclosed embodiments may be combined in a variety of ways so as to define yet further embodiments. For example, any element(s) of any embodiment may be combined with any element(s) of any other embodiment, to define still further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

In particular, one advantageous aspect of an embodiments is that a compression scheme may be adaptable to changing data characteristics. An embodiment may maintain model accuracy while optimizing compression efficiency. An embodiment may be implemented and used without the need for the creation or use of data labels. An embodiment may not necessitate in-depth knowledge of the construction or operation of the model that uses data compressed according to an embodiment. Various other advantages of one or more embodiments will be apparent from this disclosure.

### A. OVERVIEW OF ASPECTS OF ONE EXAMPLE EMBODIMENT

The following is a discussion of aspects of an example embodiment. This discussion is not intended to limit the scope of the claims or this disclosure, or the applicability of the embodiments, in any way.

One example embodiment considers edge-to-cloud machine learning classification workflows in which it is necessary to compress the input data, provided by one or more edge devices, before providing the data to the model. The cloud site may host and maintain one to more ML models that may be used to evaluate data obtained from the edge devices, and to draw inferences based on the evaluation of the data.

The data may be generated and/or collected by the edge devices. An embodiment may implemented with any type, and mix, of edge devices. Example edge devices include, but are not limited to, sensors that are able to detect and report on physical conditions of an environment, a system, or a piece of equipment. Edge devices may include IoT devices, mobile devices such as telephones, and autonomous devices such as motor vehicles. These edge devices are mentioned only by way of example and are not intended to limit the scope of this disclosure or any claims, in any way.

One embodiment is directed to an ML scenario in which an embodiment may only have access to a black-box pre-trained model at inference time, that is, when classifications are assigned to the data by the ML model, or simply ‘model.’ As a result, an embodiment may not access, need, or use, data class labels to assess the impact of data compression on the classification performance by the model.

The document “U.S. patent application Ser. No. 18/493,042, entitled OPTIMIZING LOSSY COMPRESSION FOR BLACK-BOX CLASSIFICATION MODELS WITH LABEL-LESS DATA, and filed Oct. 24, 2023,” (“Optimizing Lossy Compression”) incorporated herein in its entirety by this reference, addressed the no-label scenario with a method based on a conservative analysis procedure. In particular, that document discloses an analytical method on the KL divergences between the inference of the original data and the decompressed data, allowing us to assess the compression quality without the need to consult the labels of the data or the model weights directly. Such method was preferably applicable to static data. By way of contrast, one embodiment disclosed herein comprises a more robust and generalizable formulation that enables efficient adaptation, possibly in real time as data is collected/generated by the edge devices and/or received by the model, of compression parameters according to ongoing changes in one or more characteristics of data, such as data patterns for example, of data collected/generated by the edge devices.

In more detail, one embodiment comprises a scheme that enables determination of the compression quality of input data to a classification model while ensuring limited loss in the accuracy of the data. In this way, useful and accurate inferences may be drawn by the model, notwithstanding compression of the input data used by the model as a basis for those inferences. A method according to one embodiment utilizes only a sampling of the input data without the need for their labels, and may be applied to black-box models, that is, models regarding which knowledge of the inner workings of the model, or even knowledge of its architecture, is not required.

In one embodiment, the method is based on deriving a function that, without using any class labels, relates the desired compression quality to the expected accuracy. To achieve this, an embodiment may only need access to the output class probabilities of a classifier, that is, a model that classifies data received from, for example, one or more edge devices. Using such probabilities, one embodiment may establish limits to permitted variations in the KL (Kullback-Leibler) divergence between raw data samples and compressed data samples, for each desired compression quality. Those limits, in turn, can directly relate with expected model accuracy in terms of the inferences drawn by the model such as with respect to, for example, classifications to be applied to data received by the model. These relationships define a function accuracy=ƒ(quality) from which it becomes straightforward to determine which compression quality will satisfy accuracy constraints. Additionally, in an embodiment, the derived function may be easily updated with new data samples. To make the method adaptive, an embodiment may enable a few raw, that is, uncompressed, data samples to be sent from the edge to the cloud from time to time.

Thus, as indicated in the present disclosure, one example embodiment may comprise a method that makes the process of determining the expected accuracy of a classifier given some desired compression quality more efficient than approaches that are better suited for use with static, rather than dynamic, data. As well, an embodiment may comprise an adaptive mechanism that implements efficient updating of a relationship between (1) data compression quality and (2) model data classification accuracy, as new data arrives at the model for evaluation and classification.

### B. DETAILED DISCUSSION OF ASPECTS OF AN EXAMPLE EMBODIMENT

### B.1 Introduction

As noted herein, an example embodiment comprises an adaptive data compression scheme, and may assume that data is being transmitted from a sensor, such as a camera or microphone for example, at the edge to a cluster, which may be located at a cloud site such as a datacenter for example, that will process these data in a classification algorithm. The data traveling from the sensor may be compressed with lossy compression to maximize compression while maintaining a certain accuracy in the classifier model. With this in mind, one embodiment comprises a process capable of continuously adjusting the compression rate based on the received data, and the classifier model, without the need for new labels for the data.

Before discussing details of an example embodiment, one use case for an embodiment is presented to illustrate how an embodiment may operate, and some example circumstances in which an embodiment may be applied. In particular, consider a model that detects faces in images presented by a camera. The camera generates and compresses the images, sending them to a server for classification. During the day, the images are easier to classify, so they may be sent with more compression. However, at night, the images are harder to classify due to reduced lighting, and so the compression rate for the images may be correspondingly reduced. In this illustrative example, a method according to one embodiment may able to automatically detect the reduction in lighting, and then adapt the compression rate for each lighting condition, maintaining the accuracy of the classifier in terms of its ability to classify the image data, and reducing the communication bandwidth between the camera and the cluster.

### B.2 Discussion

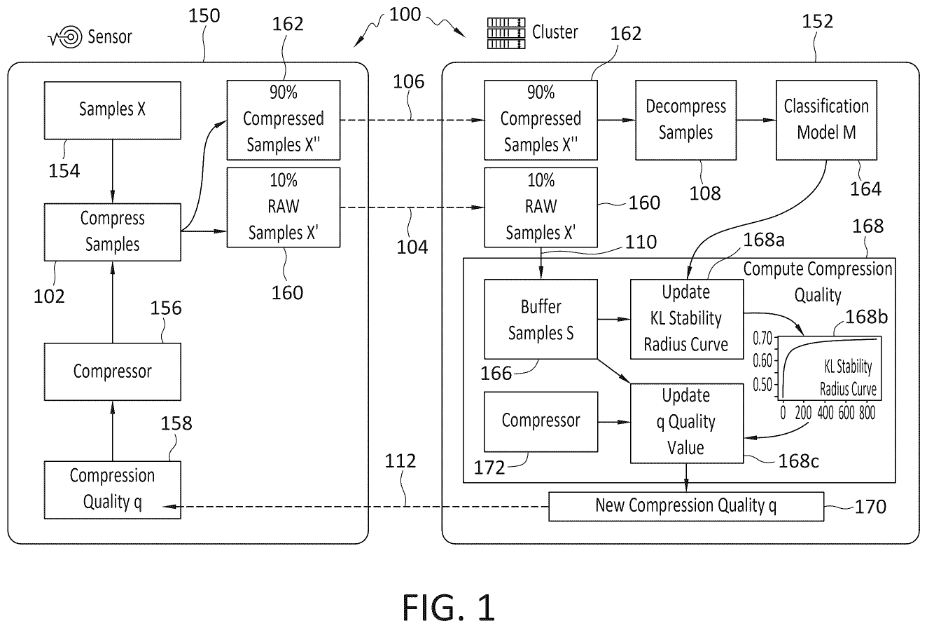

With attention now to the example of FIG. 1, a method 100 according to one embodiment is disclosed. In this example, an edge device 150, namely, a sensor generates a batch of data samples X, denoted at 154. Such samples might comprise, for example, images from a camera, although the samples could, more broadly, comprise any type of vector data. These samples need to be transmitted to a cluster 152 for classification. To achieve this, an embodiment may compress 102 the samples using a compressor 156 such as a compression algorithm C(X, q) parameterized by a quality parameter q∈[1,100], controlling the compression rate, with q=100 representing lossless compression. In one embodiment, the compression quality q 158 may be initialized with an arbitrary value and may be adapted with each batch of samples, and/or on some other basis. During this compression 102, an embodiment may reserve a percentage p=10%, or some other percentage, of the samples to be sent 104 to the cluster 152 without compression. These uncompressed samples may be referred to as raw samples 160, and the compressed data samples 162 may make up the remainder of the total data samples sent 106 to the cluster 152. The percentage p value is a parameter that may be adjusted based on considerations such as the data sample batch size and the heteroscedasticity of the samples, while also considering bandwidth limitations, that is, communication bandwidth between the edge device 150 and the cluster 152. Thus, in the example of FIG. 1, two sets of data packets are sent to the cluster 152, namely, (1−p) compressed samples X″ 162, and p raw samples X′ 160.

With continued reference to FIG. 1, in one embodiment, elements of the method 100 may be performed by/at the cluster 152. In particular, upon reaching the cluster 152, samples X″ 162 undergo decompression 108 and classification by the classifier, or model, M 164 while raw samples X′ may be stored 110 in a buffer 166. These raw samples, together with the model M 164, may be utilized to calculate 168 the new compression quality parameter q for a subsequent batch of samples generated and/or collected by the edge device 150, that is, subsequent to collection and/or generation of the data samples X 154. This process, which may be referred to herein as “compute compression quality (CCQ),” is addressed in further detail below. Briefly however, in one embodiment, CCQ computes the compression quality parameter q 170 for the subsequent data batch and transmits 112 this information back to the sensor 150, initiating the process anew with the updated q value 170. Thus, in one embodiment, the compression quality parameter q may be updated with each new data batch generated and/or collected by the sensor 150. In this way, the compression quality of the data may be updated in real time to accommodate changes that take place between data batches.

### B.2.1 CCQ

In an example of the CCQ 168, an embodiment may employ the received raw samples 160, the model 164, and the compression algorithm 172 to update the compression quality parameter q. Initially, an embodiment may accumulate the recent unperturbed raw samples X′ in a buffer S 166, with a predefined size supporting n samples. In one embodiment, older samples may be removed from the buffer S 166 using a First-In-First-Out (FIFO) mechanism. The buffer S 166 size controls the adaptation speed of the compression quality and may be configured based on the data heteroscedasticity. In experiments conducted by the inventors, discussed elsewhere herein, a value of n=250 was used. Upon arrival of new data in the buffer S 166, an embodiment may update 168a the KL Stability Radius Curve. With this updated curve, an embodiment may then estimate 168b the adapted value of q as shown in the example of FIG. 1, and then update 168c “q Quality Value.”

### B.2.2 Update KL Stability Radius Curve

Let S be the buffer containing the most recent sᵢ, i=1 . . . n unperturbed samples received from the sensor. An embodiment may can calculate the class probabilities for each sample sᵢ using the classification model M 164. Denoting the vector of class probabilities for sample sᵢ as M(sᵢ), where the class of sample sᵢ is indicated by the highest value in the vector M(sᵢ).

By selecting the two highest probabilities p₁ and p₂ from the vector M(sᵢ), an embodiment may establish a perturbation radius around sᵢ concerning the KL divergence. This radius ensures that the model does not change the classification of sᵢ if the perturbation is smaller than the radius. This radius is referred to herein as Rₖₗ(sᵢ) and defined as follows:

$${R}_{kl} ( {s}_{i} ) = {Div}_{kl} ( [ {p}_{1} , {p}_{2} ] , [ {p}_{1} - \frac{{p}_{1} - {p}_{2}}{2} , {p}_{2} + \frac{{p}_{1} - {p}_{2}}{2} ] ) ,$$

where Divₖᵢ is the Kullback-Leibler divergence, and the vector

$$[ {p}_{1} - \frac{{p}_{1} - {p}_{2}}{2} , {p}_{2} + \frac{{p}_{1} - {p}_{2}}{2} ]$$

is the nearest vector to [p₁, p₂] that does not have the first coordinate as the maximum value, i.e., it is not in the same class when classified by the classifier M.

Thus, for a given data sample s; and a perturbation sᵢ′, if

$${Div}_{kl} ( M ( {s}_{i} ) , M ( {s}_{i}^{′} ) ) < {R}_{kl} ( {s}_{i} ) ,$$

then sᵢ and sᵢ′ are classified in the same class by the classifier M 164. To calculate the KL Stability Radius Curve, an embodiment may compute the probabilities for each sample M(sᵢ), then determine the stability radius for all samples in the buffer S. This results in the set

$$\{ {R}_{kl} ( {s}_{i} ) \} , {s}_{i} ∈ S ,$$

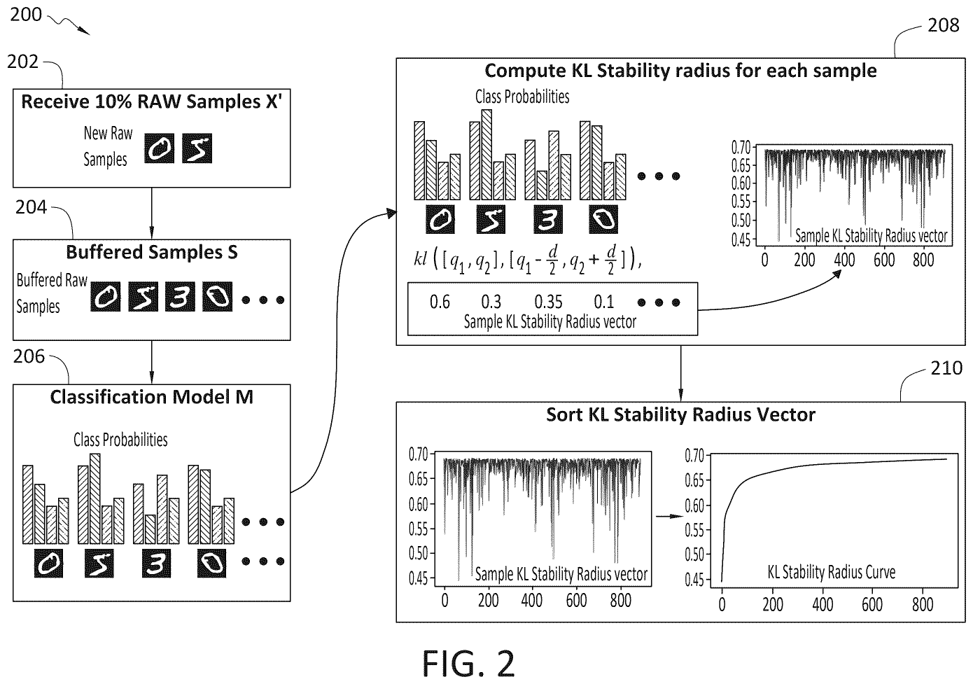

which may be subsequently sorted to obtain the KL Stability Radius Curve. An example of this process according to one embodiment is disclosed in FIG. 2.

In particular, FIG. 2 discloses an example embodiment of a stepwise process 200 for updating the KL Curve. Initially, new raw samples are received 202 and the buffer is updated 204 accordingly. Subsequently, the class probabilities are computed 206 utilizing the model. Following this, the samples' KL Stability Radius set is obtained 208. Finally, the set is sorted 210 to derive the new KL Stability Radius curve.

Using the KL Stability Radius Curve thus obtained, an embodiment may calculate the probability that any pair

$$\{ {s}_{i} , {s}_{i}^{′} \} ,$$

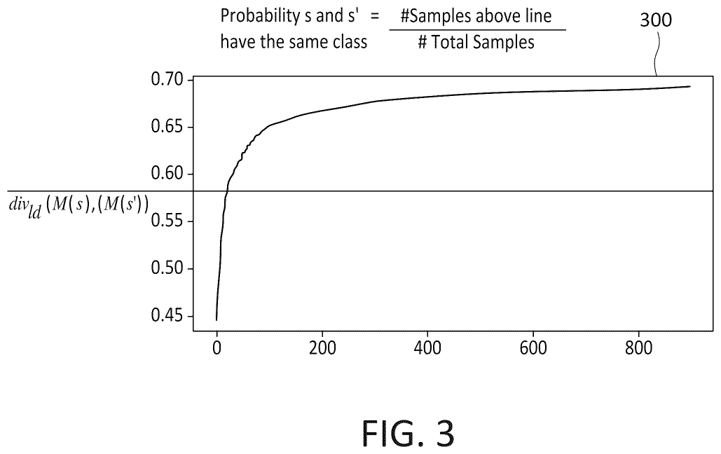

sᵢ∈S and sᵢ′ being the perturbed version of sᵢ, have the same classification label according to model M. FIG. 3 discloses a graph 300 indicating the use of the KL stability radius curve to calculate the probability of a given sample and its perturbation being classified in the same class.

In more detail, given any arbitrary value, R₀, of Rₖₗ, then all samples above R₀ preserve the original class label of sᵢ when the model M is applied to sᵢ′. If R₀=Divₖₗ(M(sᵢ), M(sᵢ′)), then an embodiment defines a lower bound on Rₖₗ that guarantees that a certain proportion of samples from S will preserve the label assigned to the raw samples sᵢ. This proportion may be denoted as the probability, P(sᵢ, sᵢ′), of sᵢ and sᵢ′ being in the same class according to M. In one embodiment, this probability may be calculated using the formula:

$$P ( {s}_{i} , {s}_{i}^{′} ) = \frac{\# \{ x > {Div}_{kl} ( M ( {s}_{i} ) , M ( {s}_{i}^{′} ) ) \vert x ∈ {R}_{kl} ( {s}_{i} ) , {s}_{i} ∈ S \}}{\#S} ,$$

where #{x>Divₖₗ(M(sᵢ), M(sᵢ′))|x∈Rₖₗ(sᵢ)} is the number of samples above the lower bound, and #S is the total number of samples in the buffer, as illustrated in the example of FIG. 3.

### B.2.3 Updating a q Quality Value

A relationship may be established between the quality parameter, q, of the compressor, C, and the expected accuracy of the label assignments M(sᵢ′). It is noted that as used here, accuracy is a measure of how much the performance of M on the original samples sᵢ is preserved when the model M is applied to the perturbed samples sᵢ′.

Thus, for a given compression quality parameter q, an embodiment may compress and decompress the raw samples stored in the buffer. In other words, an embodiment may perturb each sample sᵢ into a sample sᵢ′=C⁻¹(C(sᵢ,q),q), where C⁻¹ represents the inverse function of the compressor C, namely, a function that decompresses the output of C(sᵢ,q) according to the same quality parameter, q. As demonstrated earlier herein, an embodiment may calculate the probability for each perturbed sample sᵢ′ of being in the same class as the original sample sᵢ when classified by the model M. In an embodiment, this probability is denoted as:

$${P}_{q} ( {s}_{i} ) = P ( {s}_{i} , {C}^{- 1} ( C ( {s}_{i} , q ) , q ) ) = P ( {s}_{i} , {s}_{i}^{′} ) .$$

That is, P_{q}(sᵢ) is a proxy for the accuracy to be computed for a given sample of S. With this information, an embodiment may approximate the accuracy for a given compression quality parameter q, across S, as follows:

$$Accuracy ( q ) = Average ( {P}_{q} ( {s}_{i} ) , {s}_{i} ∈ S ) .$$

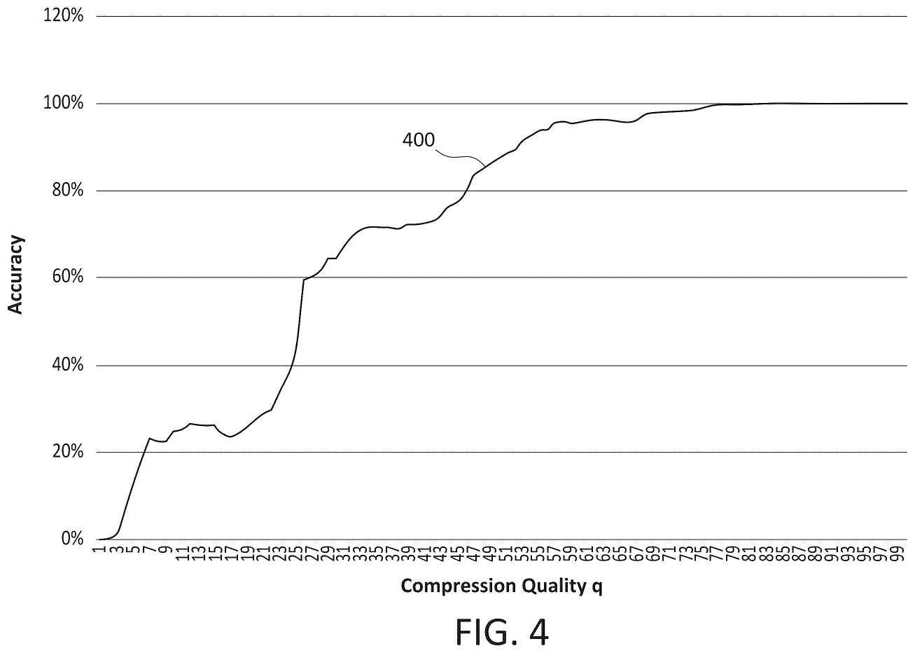

Consequently, an embodiment may calculate the expected accuracy for all values of q in the range [1,100], generating a curve that relates the compression rate to the expected model accuracy, as depicted in the example of FIG. 4.

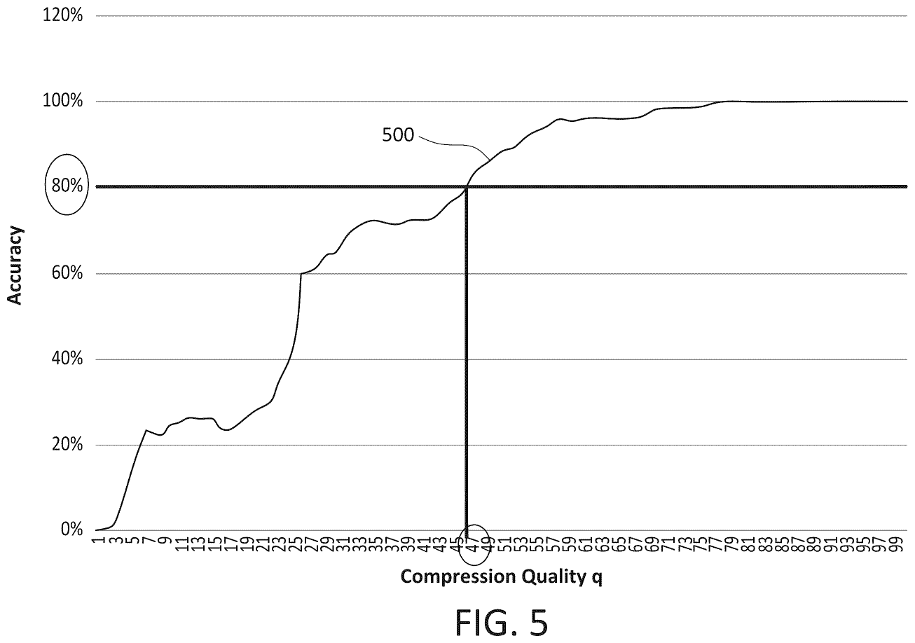

Particularly, FIG. 4 discloses a real-life example of a curve 400 depicting the relationship between compression quality (X-axis) and accuracy (Y-axis), obtained without the use of data labels. With the accuracy-compression curve 400, an embodiment may calculate the new compression quality. For example, the aim is to maintain 80% of the original model accuracy, an embodiment may determine the compression quality that satisfies this accuracy using the relation shown in FIG. 5, which illustrates the calculation of a new compression quality value q, based on a curve 500 that correlates accuracy with compression quality.

Particularly, and given the 80% accuracy threshold, the example curve 500 disclosed in FIG. 5 suggests the value q=47, which is then transmitted to the sensor and becomes the new compression quality for a subsequent data set to be compressed and transmitted, by a data source such as an edge system or device, to a recipient such as a cluster.

Thus, and as illustrated by the examples disclosed in the Figures, an embodiment may comprise an adaptive compression scheme that dynamically adjusts to data characteristics, maintaining model accuracy while optimizing compression efficiency. Moreover, such an embodiment may not necessitate the creation or use of data labels.

### C. EXAMPLE EXPERIMENTAL RESULTS

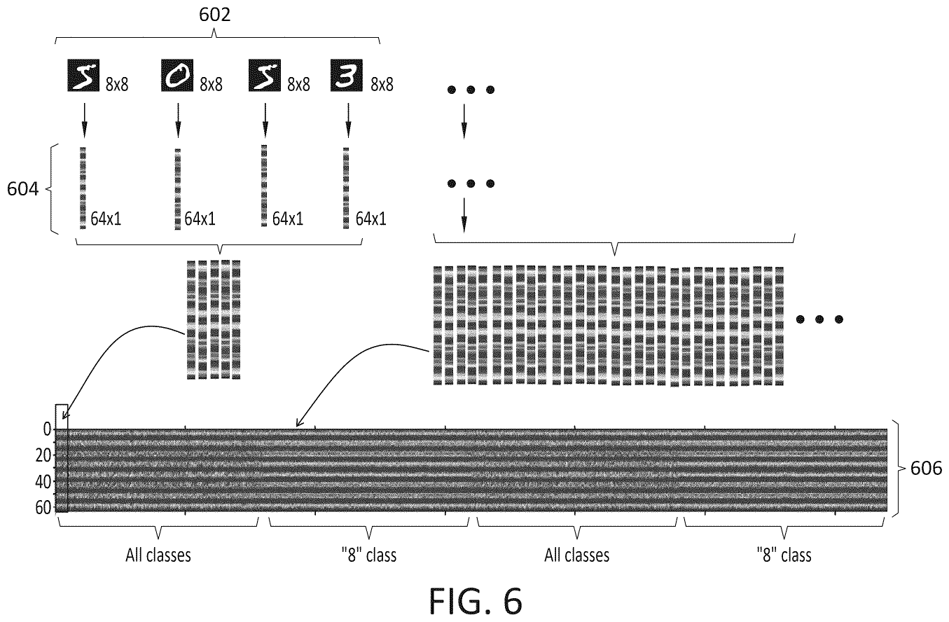

One example embodiment may aim to simulate the work of an image classifier that receives images with patterns that change over time, such as a camera capturing images during day and night. To simulate this scenario, and with reference to FIG. 6, the inventors used a reduced version of the MINIST dataset, where each image 602 has a resolution of 8×8 pixels. Each image is represented by a respective 64-dimensional vector 604 that contains a digit from 0 to 9.

From this dataset, a stream of images were simulated that randomly selects a sample respecting a predetermined class distribution. The generated samples are also disturbed by Gaussian noise. Thus, this experiment simulated a stream of images with different class probabilities over time. In the first quarter of the samples, all classes have an equal probability of occurring. In the second quarter, there is 99% chance of samples belonging to class ‘8’. The third quarter has classes with equal probabilities, and the last quarter has 99% chance of samples belonging to class ‘8’. To visualize this stream of images, the 8×8 pixel images were transformed into 64×1 vectors and concatenated them into a single image, as shown in the example of FIG. 6.

In more detail, to enhance the visualization of the image stream generated by the sensor, the 8×8 pixel images 602 were transformed into vectors 604 of 64×1 pixels and grouped as shown to generate the FIG. 606 at the bottom of the image. The samples from this stream were used in batches of 10 samples to feed an embodiment of the method. Thus, the experiment is compressing 9 images and sending 1 raw image, following the example methodology of 90% compressed batch and 10% raw. The compression quality parameter q in this test is initialized with a value of 1, and the compression algorithm used was the discrete cosine transform (DCT), although other compression algorithms may be employed in other embodiments.

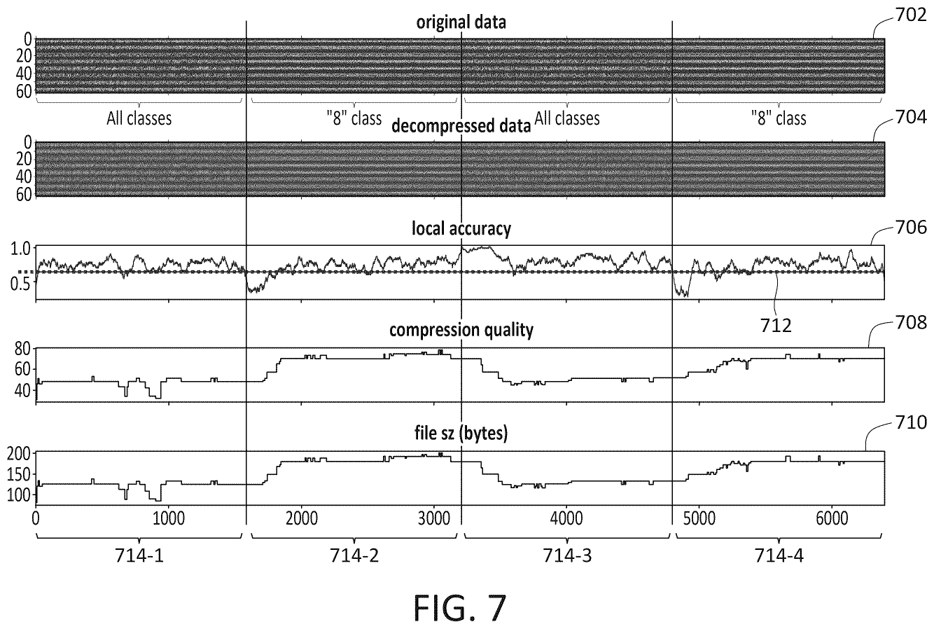

With reference now to the example of FIG. 7, there is disclosed the original data stream, the perturbed data, when compressed and decompressed, the local accuracy value, the compression quality parameter q, and the file size in bytes. In this example, the method was configured to maintain 70% of the original model's accuracy.

In more detail, in the first row of FIG. 7, there is disclosed a raw vector 702 of the image stream, while the second row represents the perturbed vector 704 after compression and decompression. The third row 706 displays the local accuracy of the model, and the fourth row 708 presents the adaptive compression quality value (q) with each batch of images. The fifth row 710 indicates the size of the compressed samples. The line 712 denotes the 70% accuracy threshold for which one embodiment of the method has been configured.

With continued reference to FIG. 7, there are disclosed four different intervals 714-1, 714-2, 714-3, and 714-4, in the data stream. From the beginning of the data stream, it can be observed that the compression quality parameter q is converging to the value 47, while the local accuracy curve remains above the line 712, indicating accuracy above 70%. As the stream enters the interval 714 where class ‘8’ is sent more frequently, the local accuracy of the model drops because this class is more difficult to compress. In the next samples, the compression quality parameter q can be seen as being adapted to the value of 72, and the accuracy curve again rises above 70%. When the stream enters the third interval 714-3, the accuracy rises well above the threshold, indicating that we can compress the data further. The compression quality is automatically adapted again to the value 47, and the process continues.

The experimental example of FIGS. 6 and 7 demonstrates that a method according to one embodiment is capable of automatically adapting the compression quality of data based on changes that have occurred, and/or are occurring, to the data of a data stream. Even in abrupt changes in the class distribution, the method can adjust the compression quality. The adaptation speed depends on the size of the buffer S. A larger buffer leads to slower adaptation, and the ideal buffer size depends on the heteroscedasticity of the stream data. It is noted that in the vast majority of samples, the accuracy was maintained above the 70% threshold, leading to the conclusion that it is possible to adapt the compression rate without the need for data labels.

### D. EXAMPLE METHODS

It is noted that any operation(s) of any of the methods disclosed herein, may be performed in response to, as a result of, and/or, based upon, the performance of any preceding operation(s). Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

### E. FURTHER EXAMPLE EMBODIMENTS

Following are some further example embodiments. These are presented only by way of example and are not intended to limit the scope of this disclosure or the claims in any way.

Embodiment 1. A method for an adaptive compression scheme that dynamically adjusts to data characteristics, maintaining model classification accuracy while optimizing compression efficiency, the method comprising: receiving, from an edge device, a sample of compressed data and a sample of raw data that has not been compressed, and the sample of compressed data and the sample of raw data are unlabeled; decompressing the compressed data to obtain decompressed data, and classifying, with an ML (machine learning) model, the decompressed data; using the ML model and the raw data to update a compression quality parameter; and transmitting the compression quality parameter to the edge device, and the compression quality parameter is usable by the edge device to control compression of a subsequent sample of compressed data.

Embodiment 2. The method as recited in any preceding embodiment, wherein data in the sample of compressed data was compressed by the edge device using a prior value of the compression quality parameter.

Embodiment 3. The method as recited in any preceding embodiment, wherein the sample of compressed data and the sample of raw data are part of an ongoing stream of data received from the edge device.

Embodiment 4. The method as recited in any preceding embodiment, wherein after receipt of the sample of raw data, a KL (Kullback-Leibler) stability radius curve is updated.

Embodiment 5. The method as recited in embodiment 4, wherein the raw sample of data is stored in a buffer, and updating the KL stability radius curve comprises: for each sample of raw data in the buffer, selecting, from a vector of class probabilities, two highest probabilities so as to establish a respective perturbation radius around each of the samples of raw data in the buffer so that a KL stability radius set is obtained; and sorting the KL stability radius set to derive the KL stability radius curve.

Embodiment 6. The method as recited in embodiment 5, wherein each of the samples of raw data is perturbed, and the probabilities for each sample of raw data comprise probabilities that the perturbed sample of raw data is in a same class as that sample of raw data prior to perturbation, when classified by the ML model.

Embodiment 7. The method as recited in embodiment 6, wherein perturbation of the samples of raw data comprises compressing the sample of raw data, and then decompressing the sample of raw data.

Embodiment 8. The method as recited in embodiment 4, wherein the KL stability curve plots compression quality on an X-axis, against accuracy of data classification performance by the ML model on a Y-axis.

Embodiment 9. The method as recited in any preceding embodiment, wherein the compression quality parameter of the sample of compressed data has a different value than a value of the compression quality parameter of earlier sample of compressed data that was received prior to receipt of the sample of compressed data.

Embodiment 10. The method as recited in any preceding embodiment, wherein the compression quality parameter is updated based on a change that has occurred between the sample of raw data and an earlier sample of raw data that was received prior to receipt of the sample of raw data.

Embodiment 11. A system, comprising hardware and/or software, operable to perform any of the operations, methods, or processes, or any portion of any of these, disclosed herein.

Embodiment 12. A non-transitory storage medium having stored therein instructions that are executable by one or more hardware processors to perform operations comprising the operations of any one or more of embodiments 1-10.

### F. EXAMPLE COMPUTING DEVICES AND ASSOCIATED MEDIA

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of this disclosure also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality. Combinations of the above should also be included within the scope of computer storage media. Such media are also examples of non-transitory storage media, and non-transitory storage media also embraces cloud-based storage systems and structures, although the scope of this disclosure is not limited to these examples of non-transitory storage media.

Computer-executable instructions comprise, for example, instructions and data which, when executed, cause a general purpose computer, special purpose computer, or special purpose processing device to perform a certain function or group of functions. As such, some embodiments may be downloadable to one or more systems or devices, for example, from a website, mesh topology, or other source. As well, the scope of this disclosure embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term module, component, client, agent, service, engine, or the like may refer to software objects or routines that execute on the computing system. These may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments may be performed in client-server environments, whether network or local environments, or in any other suitable environment. Suitable operating environments for at least some embodiments include cloud computing environments where one or more of a client, server, or other machine may reside and operate in a cloud environment.

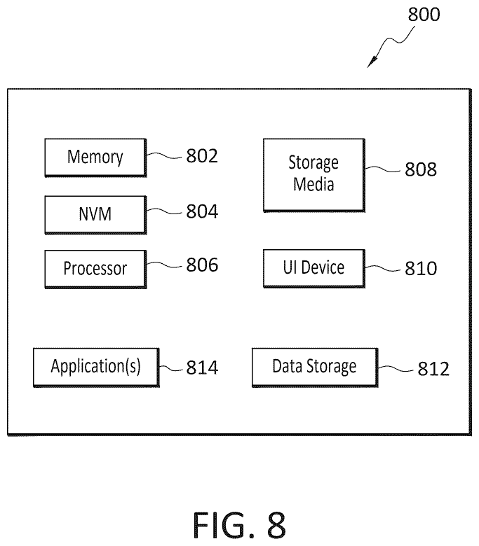

With reference briefly now to FIG. 8, any one or more of the entities disclosed, or implied, by FIGS. 1-7, and/or elsewhere herein, may take the form of, or include, or be implemented on, or hosted by, a physical computing device, one example of which is denoted at 800. As well, where any of the aforementioned elements comprise or consist of a virtual machine (VM), that VM may constitute a virtualization of any combination of the physical components disclosed in FIG. 8.

In the example of FIG. 8, the physical computing device 800 includes a memory 802 which may include one, some, or all, of random access memory (RAM), non-volatile memory (NVM) 804 such as NVRAM for example, read-only memory (ROM), and persistent memory, one or more hardware processors 806, non-transitory storage media 808, UI device 810, and data storage 812. One or more of the memory components 802 of the physical computing device 800 may take the form of solid state device (SSD) storage. As well, one or more applications 814 may be provided that comprise instructions executable by one or more hardware processors 806 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The described embodiments are to be considered in all respects only as illustrative and not restrictive. All changes which come within the meaning and range of equivalency of the claims are to be embraced within their scope.

What is claimed is:

1. A method for an adaptive compression scheme that dynamically adjusts to data characteristics, maintaining model classification accuracy while optimizing compression efficiency, the method comprising:
receiving, from an edge device, a sample of compressed data and a sample of raw data that has not been compressed, and the sample of compressed data and the sample of raw data are unlabeled;
decompressing the compressed data to obtain decompressed data, and classifying, with an ML (machine learning) model, the decompressed data;
using the ML model and the raw data to update a compression quality parameter; and
transmitting the compression quality parameter to the edge device, and the compression quality parameter is usable by the edge device to control compression of a subsequent sample of compressed data.

2. The method as recited in claim 1, wherein data in the sample of compressed data was compressed by the edge device using a prior value of the compression quality parameter.

3. The method as recited in claim 1, wherein the sample of compressed data and the sample of raw data are part of an ongoing stream of data received from the edge device.

4. The method as recited in claim 1, wherein after receipt of the sample of raw data, a KL (Kullback-Leibler) stability radius curve is updated.

5. The method as recited in claim 4, wherein the raw sample of data is stored in a buffer, and updating the KL stability radius curve comprises: for each sample of raw data in the buffer, selecting, from a vector of class probabilities, two highest probabilities so as to establish a respective perturbation radius around each of the samples of raw data in the buffer so that a KL stability radius set is obtained; and sorting the KL stability radius set to derive the KL stability radius curve.

6. The method as recited in claim 5, wherein each of the samples of raw data is perturbed, and the probabilities for each sample of raw data comprise probabilities that the perturbed sample of raw data is in a same class as that sample of raw data prior to perturbation, when classified by the ML model.

7. The method as recited in claim 6, wherein perturbation of the samples of raw data comprises compressing the sample of raw data, and then decompressing the sample of raw data.

8. The method as recited in claim 4, wherein the KL stability curve plots compression quality on an X-axis, against accuracy of data classification performance by the ML model on a Y-axis.

9. The method as recited in claim 1, wherein the compression quality parameter of the sample of compressed data has a different value than a value of the compression quality parameter of earlier sample of compressed data that was received prior to receipt of the sample of compressed data.

10. The method as recited in claim 1, wherein the compression quality parameter is updated based on a change that has occurred between the sample of raw data and an earlier sample of raw data that was received prior to receipt of the sample of raw data.

11. A non-transitory storage medium having stored therein instructions that are executable by one or more hardware processors to:
perform a method for an adaptive compression scheme that dynamically adjusts to data characteristics, maintaining model classification accuracy while optimizing compression efficiency, the method comprising operations including:
receiving, from an edge device, a sample of compressed data and a sample of raw data that has not been compressed, and the sample of compressed data and the sample of raw data are unlabeled;
decompressing the compressed data to obtain decompressed data, and classifying, with an ML (machine learning) model, the decompressed data;
using the ML model and the raw data to update a compression quality parameter; and
transmitting the compression quality parameter to the edge device, and the compression quality parameter is usable by the edge device to control compression of a subsequent sample of compressed data.

12. The non-transitory storage medium as recited in claim 11, wherein data in the sample of compressed data was compressed by the edge device using a prior value of the compression quality parameter.

13. The non-transitory storage medium as recited in claim 11, wherein the sample of compressed data and the sample of raw data are part of an ongoing stream of data received from the edge device.

14. The non-transitory storage medium as recited in claim 11, wherein after receipt of the sample of raw data, a KL (Kullback-Leibler) stability radius curve is updated.

15. The non-transitory storage medium as recited in claim 14, wherein the raw sample of data is stored in a buffer, and updating the KL stability radius curve comprises: for each sample of raw data in the buffer, selecting, from a vector of class probabilities, two highest probabilities so as to establish a respective perturbation radius around each of the samples of raw data in the buffer so that a KL stability radius set is obtained; and sorting the KL stability radius set to derive the KL stability radius curve.

16. The non-transitory storage medium as recited in claim 15, wherein each of the samples of raw data is perturbed, and the probabilities for each sample of raw data comprise probabilities that the perturbed sample of raw data is in a same class as that sample of raw data prior to perturbation, when classified by the ML model.

17. The non-transitory storage medium as recited in claim 16, wherein perturbation of the samples of raw data comprises compressing the sample of raw data, and then decompressing the sample of raw data.

18. The non-transitory storage medium as recited in claim 14, wherein the KL stability curve plots compression quality on an X-axis, against accuracy of data classification performance by the ML model on a Y-axis.

19. The non-transitory storage medium as recited in claim 11, wherein the compression quality parameter of the sample of compressed data has a different value than a value of the compression quality parameter of earlier sample of compressed data that was received prior to receipt of the sample of compressed data.

20. The non-transitory storage medium as recited in claim 11, wherein the compression quality parameter is updated based on a change that has occurred between the sample of raw data and an earlier sample of raw data that was received prior to receipt of the sample of raw data.
